(19) United States
(12) Patent Application Publication
(10) Pub. No.: US 2024/0324427 A1
(43) Pub. Date: Sep. 26, 2024

(54) DISPLAY APPARATUS

(71) Applicant: Samsung Display Co., Ltd., Yongin-si (KR)

(72) Inventors: Sangyun Lim, Yongin-si (KR); Raeyoung Kim, Yongin-si (KR); Seungin Baek, Yongin-si (KR); Younho Han, Yongin-si (KR)

(21) Appl. No.: 18/598,994

(22) Filed: Mar. 7, 2024

(30) Foreign Application Priority Data
Mar. 24, 2023 (KR) 10-2023-0039175
May 18, 2023 (KR) 10-2023-0064554

(51) Int. Cl. H10K 59/80; H10K 59/122; H10K 59/35

(52) U.S. Cl. CPC H10K 59/8792; H10K 59/122; H10K 59/35

(57) ABSTRACT

A display apparatus includes a lower substrate, first, second, and third light-emitting devices above the lower substrate, and a bank above the first, second, and third light-emitting devices, and defining first, second, and third color openings respectively corresponding to the first, second, and third light-emitting devices, wherein, in plan view, sets of the first, second, and third color openings are repeatedly arranged along a first direction and along a direction opposite to a second inclination direction, the second inclination direction being perpendicular to a first inclination direction that is between the first direction and a second direction, the second direction being perpendicular to the first direction, and wherein, in plan view, the third color opening is spaced apart from a virtual line passing through an edge of the first color opening and extending in the first direction.

### CROSS-REFERENCE TO RELATED APPLICATIONS

The present application claims priority to, and the benefit of, Korean Patent Application No. 10-2023-0039175, filed on Mar. 24, 2023, and Korean Patent Application No. 10-2023-0064554, filed May 18, 2023, in the Korean Intellectual Property Office, the content of which in their entirety are herein incorporated by reference.

### BACKGROUND

### 1. Field

One or more embodiments relate to a display apparatus capable of displaying a high-quality image.

### 2. Description of the Related Art

A display apparatus includes a plurality of sub-pixels (hereinafter, referred to as pixels). For a full-color display apparatus, a plurality of pixels may emit light of different colors. To this end, at least some pixels of the display apparatus include a color conversion unit. That is, at least part of light generated by a light emitter of some pixels is converted into light of a different color while passing through a corresponding color conversion unit and is extracted to the outside.

### SUMMARY

A related-art display apparatus may have an issue in that stripes of a corresponding color or the like appear at an edge of a display unit, and thus, a high-quality image may not be displayed.

To avoid the issue above, one or more embodiments include a display apparatus capable of displaying a high-quality image. However, the embodiments are examples, and do not limit the scope of the disclosure.

Additional aspects will be set forth in part in the description which follows and, in part, will be apparent from the description, or may be learned by practice of the presented embodiments.

According to one or more embodiments, a display apparatus includes a lower substrate, first light-emitting devices, second light-emitting devices, and third light-emitting devices above the lower substrate, and a bank above the first light-emitting devices, the second light-emitting devices, and the third light-emitting devices, and defining first color openings, second color openings, and third color openings respectively corresponding to the first light-emitting devices, the second light-emitting devices, and the third light-emitting devices, wherein, in plan view, sets of the first color opening, the second color opening, and the third color opening are repeatedly arranged along a first direction and along a direction opposite to a second inclination direction, the second inclination direction being perpendicular to a first inclination direction that is between the first direction and a second direction, the second direction being perpendicular to the first direction, and wherein, in plan view, the third color opening is spaced apart from a virtual line passing through an edge of the first color opening and extending in the first direction.

In plan view, the third color opening may be spaced apart from a third virtual line passing through an edge of the first color opening corresponding to a direction opposite to the first direction, the third virtual line extending in the second direction.

In plan view, a third virtual line may pass through an edge of the first color opening corresponding to a direction opposite to the first direction, extend in the second direction, and pass through an edge of the third color opening corresponding to the first direction.

In plan view, the third color opening may be spaced apart from first virtual line passing through an edge of the first color opening corresponding to the second direction and extending in the first direction.

In plan view, a first virtual line may pass through an edge of the first color opening corresponding to the second direction, extend in the first direction, and pass through an edge of the third color opening corresponding to a direction opposite to the second direction.

In plan view, the first color openings may be arranged along the first direction and the second direction.

In plan view, the second color openings may be arranged along the first direction and the second direction, and the third color openings may be arranged along the first direction and the second direction.

In plan view, a fourth virtual line may pass through an edge of the first color opening corresponding to the first direction, extend in the second direction, and overlap the second color opening.

In plan view, a second virtual line may pass through an edge of the first color opening corresponding to a direction opposite to the second direction, extend in the first direction, and overlap the second color opening.

In plan view, the third color opening may be spaced apart from a fifth virtual line passing through an edge of the first color opening corresponding to the direction opposite to the second inclination direction, and extending in the first inclination direction.

In plan view, a fifth virtual line may pass through an edge of the first color opening corresponding to the direction opposite to the second inclination direction, extend in the first inclination direction, and pass through an edge of the third color opening in the second inclination direction.

In plan view, a sixth virtual line may pass through an edge of the first color opening in the second inclination direction, extend in the first inclination direction, and overlap the second color opening.

In plan view, a seventh virtual line may pass through an edge of the third color opening corresponding to a direction opposite to the first direction, extend in the second direction, and overlap the second color opening.

In plan view, an eighth virtual line may pass through an edge of the third color opening in the second direction, extend in the first direction, and overlap the second color opening.

In plan view, a ninth virtual line may pass through an edge of the third color opening corresponding to the direction opposite to the second inclination direction, extend in the first inclination direction, and overlap the second color opening.

A width of the first color opening in the first inclination direction may be W1, wherein a width of an edge of the third color opening corresponding to the direction opposite to the second inclination direction, in the first inclination direction is W2, and wherein W2/W1 is about 0.55 or less.

W2/W1 may be about 0.1 or more.

A first straight line connecting a center of the first color opening to a center of the second color opening, and a second straight line connecting the center of the first color opening to a center of the third color opening, may form an acute angle therebetween.

The acute angle may be about 20° or less.

The acute angle may be about 1° or more.

The display apparatus may further include a quantum dot layer in the first color opening, and configured to convert a wavelength of light emitted from one of the first light-emitting devices into a first color wavelength.

The first color wavelength may be in a red wavelength band.

The display apparatus may further include a color filter layer above the bank, and including first color filter layers corresponding to the first color openings and configured to transmit light in a first color wavelength band, second color filter layers corresponding to the second color openings and configured to transmit light in a second color wavelength band, and third color filter layers corresponding to the third color openings and configured to transmit light in a third color wavelength band.

Other aspects of the disclosure will become more apparent from the detailed description, the claims, and the drawings.

### BRIEF DESCRIPTION OF THE DRAWINGS

The above and other aspects of embodiments will be more apparent from the following description taken in conjunction with the accompanying drawings, in which:

FIG. 1 is a plan view schematically illustrating a display apparatus, according to one or more embodiments;

FIG. 2 is a plan view schematically illustrating a portion A of the display apparatus of FIG. 1;

FIG. 3 is a cross-sectional view schematically illustrating the display apparatus of FIG. 2, taken along the line B-B′ of FIG. 2;

FIG. 4 is an enlarged plan view schematically illustrating a portion of the display apparatus of FIG. 2;

FIG. 5 is a graph schematically illustrating a digital cinema initiative (DCI) color space and a color space of the display apparatus of FIG. 1;

FIG. 6 is an enlarged graph illustrating a portion C of FIG. 5;

FIG. 7 is a graph illustrating a color reproduction rate according to a width ratio between openings of a bank of the display apparatus of FIG. 1; and

FIG. 8 is a cross-sectional view schematically illustrating a display apparatus, according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The present disclosure covers all modifications, equivalents, and replacements within the idea and technical scope of the present disclosure. Further, each of the features of the various embodiments of the present disclosure may be combined or combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions, such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression, such as “at least one of A and B” and “at least one of A or B” may include A, B, or A and B. As used herein, “or” generally means “and/or,” and the term “and/or” includes any and all combinations of one or more of the associated listed items. For example, the expression, such as “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5%of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

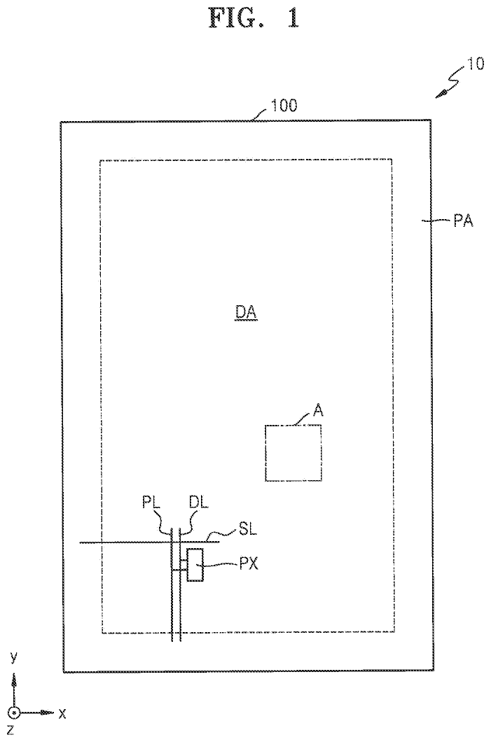

FIG. 1 is a plan view schematically illustrating a display apparatus, according to one or more embodiments.

As shown in FIG. 1, the display apparatus includes a display panel 10. The display apparatus may be any apparatus including the display panel 10. For example, the display apparatus may be any of various devices, such as a smartphone, a tablet, a laptop, a television, or a billboard.

The display panel 10 includes a display area DA, and includes a peripheral area PA located outside the display area DA. In FIG. 1, the display area DA has a rectangular shape. However, the disclosure is not limited thereto. The display area DA may have any of various shapes, such as a circular shape, an elliptical shape, a polygonal shape, or another shape.

The display area DA is a portion where an image is displayed, and a plurality of pixels PX may be located in the display area DA. Each pixel PX may include a display device/light-emitting device, such as an organic light-emitting diode. Each pixel PX may emit, for example, red light, green light, or blue light. The pixel PX may have a pixel circuit including a thin-film transistor (TFT) and a storage capacitor. The pixel circuit may be connected to a scan line SL through which a scan signal is transmitted, a data line DL that intersects the scan line SL and through which a data signal is transmitted, and a driving voltage line PL through which a driving voltage is supplied. The scan line SL may extend in an x direction, and the data line DL and the driving voltage line PL may extend in a y direction.

The pixel PX may emit light having a luminance corresponding to an electrical signal from the pixel circuit that is electrically connected. The display area DA may display a certain image through light emitted from the pixel PX. For reference, the pixel PX may be defined as an area where any one of red light, green light, or blue light is emitted as described above.

The peripheral area PA may be a portion where the pixel PX is not located and where an image is not displayed. A power supply wiring for driving the pixel PX may be located in the peripheral area PA. Also, a printed circuit board including a driving circuit unit or a terminal unit to which a driver IC is connected may be located in the peripheral area PA.

For reference, because the display panel 10 includes a lower substrate 100, the lower substrate 100 may include the display area DA and the peripheral area PA.

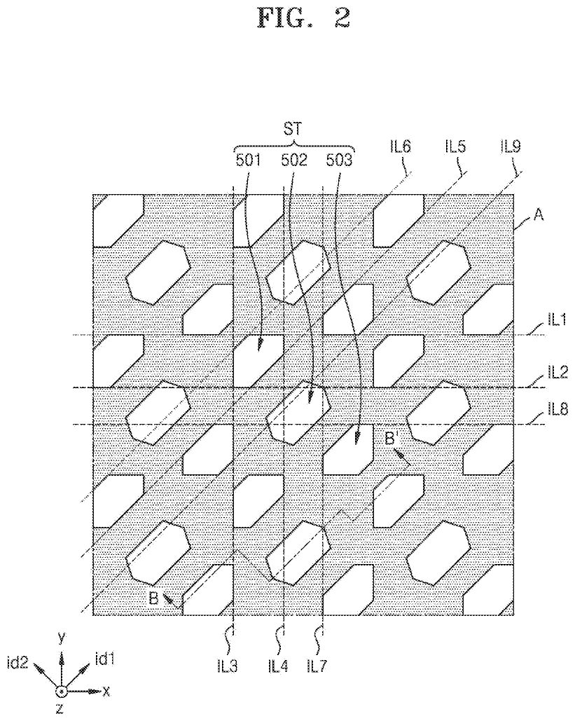

FIG. 2 is a plan view schematically illustrating a portion A of the display apparatus of FIG. 1. For reference, FIG. 2 illustrates a first color opening 501, a second color opening 502, and a third color opening 503 of a bank 500 included in the display apparatus of FIG. 1. Each of the first color opening 501, the second color opening 502, and the third color opening 503 may correspond to a pixel that emits light belonging to a corresponding wavelength band. For example, the first color opening 501 may correspond to a pixel that emits red light having a first color wavelength, the second color opening 502 may correspond to a pixel that emits green light having a second color wavelength, and the third color opening 503 may correspond to a pixel that emits blue light having a third color wavelength.

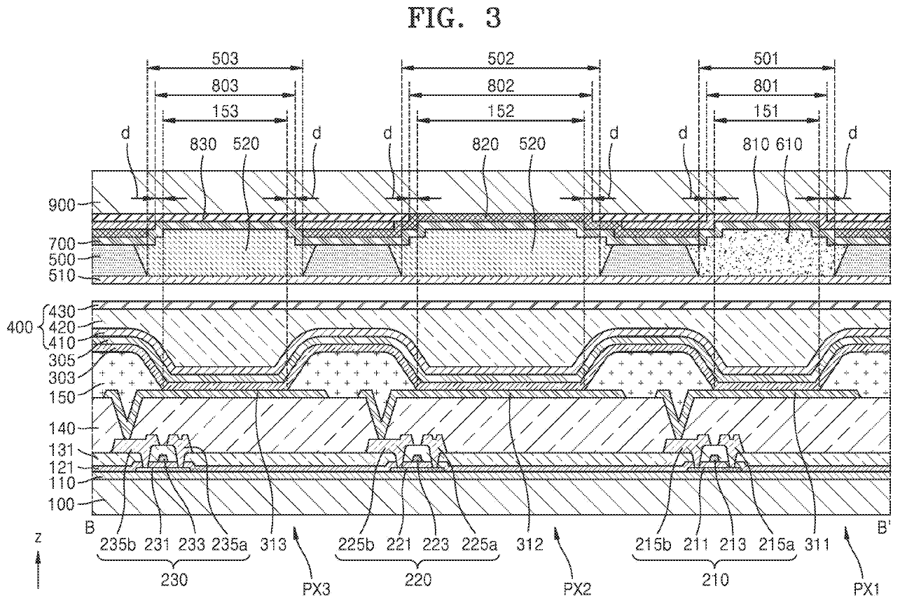

As described below, when viewed in a direction (a z axis direction) perpendicular to the lower substrate 100 (see FIG. 3) (e.g., when viewed in a plan view), when a direction between a first direction (a+x direction) and a second direction (a +y direction), which is perpendicular to the first direction, is a first inclination direction (a +id1 direction), as shown in FIG. 2, a set ST of the first color opening 501, the second color opening 502, and the third color opening 503 may be repeatedly arranged along a direction (a −id2 direction) opposite to a second inclination direction (a +id2 direction), which is perpendicular to the first inclination direction. In addition, the set ST of the first color opening 501, the second color opening 502, and the third color opening 503 may be repeatedly arranged along the first direction (the +x direction). Such an arrangement of the first color opening 501, the second color opening 502, and the third color opening 503 will be described below in detail.

FIG. 3 is a cross-sectional view schematically illustrating the portion A of the display apparatus of FIG. 2, taken along the line B-B′ of FIG. 2.

The display apparatus may include the lower substrate 100, a first pixel electrode 311, a second pixel electrode 312, a third pixel electrode 313, a pixel-defining film 150, an encapsulation layer 400, an upper substrate 900, a bank 500, and a quantum dot layer 610.

The lower substrate 100 may include glass, a metal, or a polymer resin. The lower substrate 100 may include a polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. However, various modifications may be made. For example, the lower substrate 100 may have a multi-layer structure including two layers each including a polymer resin, and a barrier layer including an inorganic material (e.g., silicon oxide, silicon nitride, or silicon oxynitride) between the two layers.

The first pixel electrode 311, the second pixel electrode 312, and the third pixel electrode 313 are located over the lower substrate 100. In addition to the first pixel electrode 311, the second pixel electrode 312, and the third pixel electrode 313, a first thin-film transistor 210, a second thin-film transistor 220, and a third thin-film transistor 230 respectively electrically connected to the first pixel electrode 311, the second pixel electrode 312, and the third pixel electrode 313 may also be located over the lower substrate 100. That is, as shown in FIG. 3, the first pixel electrode 311 may be electrically connected to the first thin-film transistor 210, the second pixel electrode 312 may be electrically connected to the second thin-film transistor 220, and the third pixel electrode 313 may be electrically connected to the third thin-film transistor 230. The first pixel electrode 311, the second pixel electrode 312, and the third pixel electrode 313 may be located over a planarization layer 140 that is located over the lower substrate 100.

The first thin-film transistor 210 may include a first semiconductor layer 211 including amorphous silicon, polycrystalline silicon, an organic semiconductor material, or an oxide semiconductor material, a first gate electrode 213, a first source electrode 215a, and a first drain electrode 215b. The first gate electrode 213 may include any of various conductive materials and may have any of various layer structures. For example, the first gate electrode 213 may include a molybdenum (Mo) layer and an aluminum (Al) layer. In this case, the first gate electrode 213 may have a layer structure including Mo/Al/Mo. Alternatively, the first gate electrode 213 may include a TiNx layer, an aluminum (Al) layer, and/or a titanium (Ti) layer. Each of the first source electrode 215a and the first drain electrode 215b may also include any of various conductive materials and may have any of various layer structures. For example, each of the first source electrode 215a and the first drain electrode 215b may include a Ti layer, an Al layer, and/or a copper (Cu) layer. In this case, each of the first source electrode 215a and the first drain electrode 215b may have a layer structure including Ti/Al/Ti.

Although the first thin-film transistor 210 includes the first source electrode 215a and the first drain electrode 215b in FIG. 3, the disclosure is not limited thereto. For example, a source region of the first semiconductor layer 211 of the first thin-film transistor 210 may be integrally formed with a drain region of a semiconductor layer of another thin-film transistor, and in this case, the first thin-film transistor 210 may not include the first source electrode 215a. The first source electrode 215a and/or the first drain electrode 215b may be a part of a wiring.

To ensure insulation between the first semiconductor layer 211 and the first

gate electrode 213, a gate insulating film 121 including an inorganic material, such as silicon oxide, silicon nitride, and/or silicon oxynitride, may be located between the first semiconductor layer 211 and the first gate electrode 213. In addition, an interlayer insulating film 131 including an inorganic material, such as silicon oxide, silicon nitride, and/or silicon oxynitride, may be located over the first gate electrode 213, and the first source electrode 215a and the first drain electrode 215b may be located over the interlayer insulating film 131. Such an insulating film including an inorganic material may be formed by using chemical vapor deposition (CVD) or atomic layer deposition (ALD). This applies to the following embodiments and modifications thereof.

A buffer layer 110 including an inorganic material, such as silicon oxide, silicon nitride, and/or silicon oxynitride may be located between the lower substrate 100 and the first thin-film transistor 210 having the above structure. The buffer layer 110 may increase the smoothness of a top surface of the lower substrate 100, or may prevent, reduce, or minimize penetration of impurities from the lower substrate 100 or the like into the first semiconductor layer 211 of the first thin-film transistor 210.

The second thin-film transistor 220 located in a second pixel PX2 may include a second semiconductor layer 221, a second gate electrode 223, a second source electrode 225a, and a second drain electrode 225b. The third thin-film transistor 230 located in a third pixel PX3 may include a third semiconductor layer 231, a third gate electrode 233, a third source electrode 235a, and a third drain electrode 235b. A structure of the second thin-film transistor 220 and a structure of the third thin-film transistor 230 may be the same as, or similar to, a structure of the first thin-film transistor 210 located in a first pixel PX1, and thus, a description thereof will be omitted.

The planarization layer 140 may be located over the first thin-film transistor 210. For example, if a first light-emitting device including the first pixel electrode 311 is located over the first thin-film transistor 210 as shown in FIG. 3, the planarization layer 140 covering the first thin-film transistor 210 may have a substantially flat top so that the first pixel electrode 311 of the first light-emitting device is located over the substantially flat top surface. The planarization layer 140 may include an organic material, such as acryl, benzocyclobutene (BCB), or hexamethyldisiloxane (HMDSO). Although the planarization layer 140 has a single-layer structure in FIG. 3, various modifications may be made. For example, the planarization layer 140 may have a multi-layer structure.

The first light-emitting device, which is an organic light-emitting device including the first pixel electrode 311, a counter electrode 305, and an intermediate layer 303 between the first pixel electrode 311 and the counter electrode 305 and including an emission layer, may be located in the first pixel PX1. The first pixel electrode 311 may be electrically connected to the first thin-film transistor 210 by contacting any one of the first source electrode 215a or the first drain electrode 215b through a contact hole formed in the planarization layer 140 as shown in FIG. 3. The first pixel electrode 311 may include a light-transmitting conductive layer formed of a light-transmitting conductive oxide, such as ITO, In₂O₃, or IZO, and a reflective layer formed of a metal, such as aluminum (Al) or silver (Ag). For example, the first pixel electrode 311 may have a three-layer structure including ITO/Ag/ITO.

A second light-emitting device, which is an organic light-emitting device including the second pixel electrode 312, the counter electrode 305, and the intermediate layer 303 between the second pixel electrode 312 and the counter electrode 305 and including an emission layer, may be located in the second pixel PX2. A third light-emitting device, which is an organic light-emitting device including the third pixel electrode 313, the counter electrode 305, and the intermediate layer 303 between the third pixel electrode 313 and the counter electrode 305 and including an emission layer, may be located in the third pixel PX3. The second pixel electrode 312 is electrically connected to the second thin-film transistor 220 by contacting any one of the second source electrode 225a or the second drain electrode 225b through a contact hole formed in the planarization layer 140. The third pixel electrode 313 is electrically connected to the third thin-film transistor 230 by contacting any one of the third source electrode 235a or the third drain electrode 235b through a contact hole formed in the planarization layer 140. The description of the first pixel electrode 311 may apply to the second pixel electrode 312 and the third pixel electrode 313.

As described above, the intermediate layer 303 including an emission layer may be located over the second pixel electrode 312 of the second pixel PX2 and the third pixel electrode 313 of the third pixel PX3, as well as on the first pixel electrode 311 of the first pixel PX1. The intermediate layer 303 may be integrally formed over the first pixel electrode 311, the second pixel electrode 312, and the third pixel electrode 313. If suitable, the intermediate layer 303 may be patterned over the first pixel electrode 311, the second pixel electrode 312, and the third pixel electrode 313. The intermediate layer 303 may include a hole injection layer, a hole transport layer, and/or an electron transport layer in addition to the emission layer, if suitable, and these layers of the intermediate layer 303 may also be integrally formed over the first pixel electrode 311, the second pixel electrode 312, and the third pixel electrode 313. Some of the layers included in the intermediate layer 303 may be patterned and located over the first pixel electrode 311, the second pixel electrode 312, and the third pixel electrode 313, if suitable.

The emission layer included in the intermediate layer 303 may emit light having the second color wavelength and light having the third color wavelength. The second color wavelength may belong to a wavelength band of, for example, about 495 nm to about 570 nm, and the third color wavelength may belong to a wavelength band of, for example, about 450 nm to about 495 nm. The emission layer may include a material capable of emitting light having the second color wavelength and a material capable of emitting light having the third color wavelength. In this regard, the emission layer included in the intermediate layer 303 may include a second color emission layer and a third color emission layer. That is, the second color emission layer and the third color emission layer may be an integrated layer rather than separate layers. The intermediate layer 303 may include a plurality of emission layers, instead of one emission layer. For example, the intermediate layer 303 may have a structure in which the second color emission layer and the third color emission layer are separated from each other and are stacked, and in which a charge generation layer is located between the second color emission layer and the third color emission layer. In this case, a hole transport layer or an electron transport layer may be located between the second color emission layer and the charge generation layer, and between the third color emission layer and the charge generation layer. The second color emission layer may include a material capable of emitting light having the second color wavelength, and the third color emission layer may include a material capable of emitting light having the third color wavelength.

The counter electrode 305 on the intermediate layer 303 may also be integrally formed over the first to third pixel electrodes 311, 312, and 313. The counter electrode 305 may include a light-transmitting conductive layer formed of ITO, In₂O₃, or IZO, or may include a transflective film including a metal, such as Al, Li, Mg, Yb, or Ag. For example, the counter electrode 305 may be a transflective film including MgAg, AgYb, Yb/MgAg, or Li/MgAg.

The pixel-defining film 150 may be located over the planarization layer 140. The pixel-defining film 150 has pixel openings corresponding to pixels. That is, the pixel-defining film 150 covers edges of the first pixel electrode 311, the second pixel electrode 312, and the third pixel electrode 313, and includes a first pixel opening 151, a second pixel opening 152, and a third pixel opening 153 through which a central portion of the first pixel electrode 311, a central portion of the second pixel electrode 312, and a central portion of the third pixel electrode 313 are respectively exposed. As shown in FIG. 3, the pixel-defining film 150 may increase a distance between the counter electrode 305, and an edge of each of the first pixel electrode 311, the second pixel electrode 312, and the third pixel electrode 313, to reduce or prevent the likelihood of an arc or the like occurring on the edge of each of the first pixel electrode 311, the second pixel electrode 312, and the third pixel electrode 313. The pixel-defining film 150 may include an organic material, such as polyimide or hexamethyldisiloxane (HMDSO).

The first to third light-emitting devices, which are organic light-emitting devices including the first pixel electrode 311, the second pixel electrode 312, and the third pixel electrode 313, the intermediate layer 303 including the emission layer, and the counter electrode 305, may be easily degraded by moisture or oxygen. Accordingly, to protect the first to third light-emitting devices from external moisture or oxygen, the display apparatus may include the encapsulation layer 400 covering the first to third light-emitting devices.

The encapsulation layer 400 may include at least one inorganic encapsulation layer and at least one organic encapsulation layer. For example, the encapsulation layer 400 may include a first inorganic encapsulation layer 410, a second inorganic encapsulation layer 430, and an organic encapsulation layer 420 between the first inorganic encapsulation layer 410 and the second inorganic encapsulation layer 430.

Each of the first inorganic encapsulation layer 410 and the second inorganic encapsulation layer 430 may include at least one inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO or ZnO₂), and may be formed by using CVD or the like. The organic encapsulation layer 420 may include a polymer-based material. Examples of the polymer-based material may include a silicone-based resin, an acrylic resin (e.g., polymethyl methacrylate or polyacrylic acid), an epoxy-based resin, polyimide, and polyethylene.

Because the first inorganic encapsulation layer 410 formed by using CVD has a substantially uniform thickness, a top surface of the first inorganic encapsulation layer 410 may not be flat as shown in FIG. 3. However, the organic encapsulation layer 420 may have a substantially flat top surface, and thus, the second inorganic encapsulation layer 430 on the organic encapsulation layer 420 may have a substantially flat top surface.

The upper substrate 900 may be located over the lower substrate 100 so that the first to third light-emitting devices including the first pixel electrode 311, the second pixel electrode 312, the third pixel electrode 313, the intermediate layer 303, and the counter electrode 305 are located between the upper substrate 900 and the lower substrate 100. The upper substrate 900 may include glass, a metal, or a polymer resin. The upper substrate 900 may include a polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. However, various modifications may be made. For example, the upper substrate 900 may have a multi-layer structure including two layers each including a polymer resin, and a barrier layer including an inorganic material (e.g., silicon oxide, silicon nitride, or silicon oxynitride) between the two layers.

The bank 500 overlaps a bottom surface of the upper substrate 900 facing the lower substrate 100 (e.g., in a-z direction). That is, the bank 500 is located over the first to third light-emitting devices. The bank 500 includes the first color opening 501, the second color opening 502, and the third color opening 503. The first to third color openings 501 to 503 of the bank 500 may correspond to the first to third light-emitting devices. In detail, the first color opening 501 of the bank 500 may correspond to the first pixel opening 151 of the pixel-defining film 150 through which the first pixel electrode 311 is exposed, the second color opening 502 of the bank 500 may correspond to the second pixel opening 152 of the pixel-defining film 150 through which the second pixel electrode 312 is exposed, and the third color opening 503 of the bank 500 may correspond to the third pixel opening 153 of the pixel-defining film 150 through which the third pixel electrode 313 is exposed.

That is, when viewed in the direction (the z axis direction) perpendicular to the lower substrate 100, the first color opening 501 of the bank 500 may overlap the first pixel opening 151 of the pixel-defining film 150 through which the first pixel electrode 311 is exposed, the second color opening 502 of the bank 500 may overlap the second pixel opening 152 of the pixel-defining film 150 through which the second pixel electrode 312 is exposed, and the third color opening 503 of the bank 500 may overlap the third pixel opening 153 of the pixel-defining film 150 through which the third pixel electrode 313 is exposed. Accordingly, when viewed in the direction (the z axis direction) perpendicular to the lower substrate 100, a shape of an edge of each of the first to third color openings 501 to 503 of the bank 500 may be the same as, or similar to, a shape of an edge of a pixel opening corresponding to the pixel-defining film 150. As such, the first color opening 501 of the bank 500 may correspond to the first pixel electrode 311, the second color opening 502 of the bank 500 may correspond to the second pixel electrode 312, and the third color opening 503 of the bank 500 may correspond to the third pixel electrode 313.

In this case, when viewed in the direction (the z axis direction) perpendicular to the lower substrate 100, the area of the first color opening 501 of the bank 500 may be greater than the area of the first pixel opening 151 of the pixel-defining film 150, the area of the second color opening 502 of the bank 500 may be greater than the area of the second pixel opening 152 of the pixel-defining film 150, and the area of the third color opening 503 of the bank 500 may be greater than the area of the third pixel opening 153 of the pixel-defining film 150. Accordingly, light generated from the first pixel opening 151 of the pixel-defining film 150 may be sufficiently incident into the first color opening 501 of the bank 500, light generated from the second pixel opening 152 of the pixel-defining film 150 may be sufficiently incident into the second color opening 502 of the bank 500, and light generated from the third pixel opening 153 of the pixel-defining film 150 may be sufficiently incident into the third color opening 503 of the bank 500.

The bank 500 may be formed of any of various materials. For example, the bank 500 may be formed of an organic material, such as acryl, BCB, or HMDSO. If suitable, the bank 500 may include a photoresist material, and thus, the bank 500 may be easily formed through a process, such as exposure and development. In a manufacturing process, the bank 500 including the first to third color openings 501 to 503 may be formed on the upper substrate 900, the quantum dot layer 610, which is described below, may be formed in the first color opening 501 of the bank 500, and then, the lower substrate 100 and the upper substrate 900 may be attached to each other by using an adhesive member or the like. Because the bank 500 is formed on the upper substrate 900 through a process, such as exposure and development, the area of a surface of the bank 500 facing the lower substrate 100 (in the-z direction) may be greater than the area of a surface of the bank 500 facing the upper substrate 900 (in a +z direction). Accordingly, as shown in FIG. 3, a cross-sectional area of the bank 500 may increase away from the upper substrate 900, and thus, the bank 500 may have a reverse tapered shape with respect to the upper substrate 900.

The quantum dot layer 610 may be located in the first color opening 501 of the bank 500. When viewed in the direction (the z axis direction) perpendicular to the lower substrate 100, the quantum dot layer 610 may overlap the first pixel electrode 311. That is, when viewed in the direction (the z axis direction) perpendicular to the lower substrate 100, the quantum dot layer 610 may overlap the first light-emitting device. Because the quantum dot layer 610 includes quantum dots capable of converting a wavelength of incident light, the quantum dot layer 610 may convert light having either the second color wavelength or the third color wavelength passing through the quantum dot layer 610 into light having the first color wavelength. The first color wavelength may belong to a wavelength band of, for example, about 625 nm to about 780 nm. That is, light having the first color wavelength may be red light. However, the disclosure is not limited thereto, and a wavelength band to which a wavelength of light to be converted by the quantum dot layer 610 belongs, and a wavelength band to which a wavelength of light after conversion belongs may be changed differently.

In the quantum dot layer 610, quantum dots may be dispersed in a resin. Quantum dots may refer to semiconductor compound crystals, and may include any material capable of emitting light having various wavelengths according to sizes of crystals. A diameter of each of the quantum dots may range from, for example, about 1 nm to about 10 nm.

Quantum dots may be synthesized by using a wet chemical process, metal organic chemical deposition, molecular beam epitaxy, or the like. A wet chemical process is a method of mixing an organic solvent with a precursor material and then growing quantum dot crystals. In a wet chemical process, if crystals are grown, because an organic solvent naturally functions as a dispersant coordinated on quantum dot crystal surfaces and controls the growth of the crystals, the wet chemical process is easier than a vapor deposition method, such as organic metal chemical vapor deposition (MOCVD) or molecular beam epitaxy (MBE). Also, the wet chemical process is inexpensive and may control the growth of quantum dot particles.

Such quantum dots may include a group II-VI semiconductor compound, a group III-V semiconductor compound, a group III-VI semiconductor compound, a group I-III-VI semiconductor compound, a group IV-VI semiconductor compound, a group IV element or compound, or any combination thereof.

Examples of the group II-VI semiconductor compound may include a binary compound, such as CdS, CdSe, CdTe, ZnS, ZnSe, ZnTe, ZnO, HgS, HgSe, HgTe, MgSe, or MgS, a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS, a quaternary compound, such as CdZnSeS, CdZnSeTe, CdZnSTe, CdHgSeS, CdHgSeTe, CdHgSTe, HgZnSeS, HgZnSeTe, or HgZnSTe, and/or any combination thereof.

Examples of the group III-V semiconductor compound may include a binary compound, such as GaN, GaP, GaAs, GaSb, AlN, AlP, AlAs, AlSb, InN, InP, InAs, or InSb, a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, or InPSb, a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb, and/or any combination thereof. The group III-V semiconductor compound may further include a group II element. Examples of the group III-V semiconductor compound further including the group II element may include InZnP, InGaZnP, and/or InAlZnP.

Examples of the group III-VI semiconductor compound may include a binary compound, such as GaS, GaSe, GazSe₃, GaTe, InS, In₂S₃, InSe, In₂Se₃, or InTe, a ternary compound, such as AgInS, AgInS₂, CuInS, CuInS₂, InGaS₃, or InGaSe₃, and/or any combination thereof.

Examples of the group I-III-VI semiconductor compound may include a ternary compound, such as AgInS, AgInS₂, CuInS, CuInS₂, CuGaO₂, AgGaO₂, or AgAlO₂, and/or any combination thereof.

Examples of the group IV-VI semiconductor compound may include a binary compound, such as SnS, SnSe, SnTe, PbS, PbSe, or PbTe, a ternary compound, such as SnSeS, SnSeTe, SnSTe, PbSeS, PbSeTe, PbSTe, SnPbS, SnPbSe, or SnPbTe, a quaternary compound, such as SnPbSSe, SnPbSeTe, or SnPbSTe, and/or any combination thereof.

Examples of the group IV element or compound may include a single-element, such as Si or Ge, a binary compound, such as SiC or SiGe, and/or any combination thereof.

Elements included in a multi-element compound, such as a binary compound, a ternary compound, or a quaternary compound may exist in particles at a uniform concentration or a non-uniform concentration.

A quantum dot may have a core-shell structure or a single structure having a

uniform element concentration in the quantum dot. For example, a material included in a core and a material included in a shell may be different from each other. The shell of the quantum dot may serve as a protective layer for maintaining semiconductor characteristics by reducing or preventing chemical denaturation of the core and/or a charging layer for providing electrophoretic characteristics to the quantum dot. The shell may have a single layer or multi-layer structure. An interface between the core and the shell may have a concentration gradient in which a concentration of an element in the shell gradually decreases toward the center.

Examples of the shell of the quantum dot may include an oxide of a metal or a non-metal, a semiconductor compound, and a combination thereof. Examples of the oxide of the metal or the non-metal may include a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, a ternary compound, such as MgAl₂O₄, CoFe₂O₄, NiFe₂O₄, or CoMn₂O₄, and/or any combination thereof. Examples of the semiconductor compound may include, as described above, a group II-VI semiconductor compound, a group III-V semiconductor compound, a group III-VI semiconductor compound, a group I-III-VI semiconductor compound, a group IV-VI semiconductor compound, and/or any combination thereof. Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or any combination thereof.

A quantum dot may have a full width at half maximum (FWHM) of an emission wavelength spectrum of about 45 nm or less, for example about 40 nm or less, and as another example about 30 nm or less. When the FWHM is in this range, color purity or color reproducibility may be improved. Also, because light emitted through the quantum dot is emitted in all directions, an optical viewing angle may be improved. Also, for example, a quantum dot may be a spherical, pyramid, multi-arm, or cubic-shaped nano particle, nano-tube, nano-wire, nano-fiber, or nano-plate particle. Because an energy band gap may be adjusted by adjusting a size of a

quantum dot, light in a desired wavelength band may be obtained through a quantum dot emission layer. Accordingly, a light-emitting device for emitting light having various wavelengths may be realized by using quantum dots having different sizes. For example, a size of a quantum dot may be selected to emit light having the first color wavelength. The first color wavelength may belong to a wavelength band of, for example, about 625 nm to about 780 nm.

The quantum dot layer 610 may include a scatterer. Because incident light is scattered by the scatterer included in the quantum dot layer 610, the incident light may be efficiently converted by the quantum dots in the quantum dot layer 610. The scatterer is not particularly limited as long as it is capable of partially scattering transmitted light by forming an optical interface between the scatterer and a light-transmitting resin included in the quantum dot layer 610. For example, the scatterer may be metal oxide particles or organic particles. Examples of a metal oxide for the scatterer may include titanium oxide (TiO₂), zirconium oxide (ZrO₂), aluminum oxide (Al₂O₃), indium oxide (In₂O₃), zinc oxide (ZnO or ZnO₂), and/or tin oxide (SnO₂), and examples of an organic material for the scatterer may include an acrylic resin and/or a urethane-based resin. The scatterer may scatter light in several directions regardless of an angle of incidence without substantially converting a wavelength of incident light. Accordingly, the scatterer may improve side visibility of the display apparatus. Also, the scatterer included in the quantum dot layer 610 may increase the probability that light incident on the quantum dot layer 610 meets the quantum dots, thereby improving light conversion efficiency.

The light-transmitting resin included in the quantum dot layer 610 may be any resin as long as it has suitable scattering characteristics for the scatterer and is a light-transmitting material. For example, a polymer resin, such as acrylic resin, an imide-based resin, an epoxy-based resin, BCB, or HMDSO may be used as a material for forming the quantum dot layer 610. The quantum dot layer 610 including the light-transmitting resin, the scatterer, and the quantum dots may be located in the first color opening 501.

Color filter layers may be located between the upper substrate 900 and the bank 500. When viewed in the direction perpendicular to the lower substrate 100 (e.g., when viewed in plan view), a first color filter layer 810 may be located in the first pixel PX1 to overlap the first light-emitting device. Further, a second color filter layer 820 may be located in the second pixel PX2 to overlap the second light-emitting device. Also, a third color filter layer 830 may be located in the third pixel PX3 to overlap the third light-emitting device. That is, a portion of the first color filter layer 810 not overlapping other color filter layers may have a shape corresponding to the first color opening 501 of the bank 500, a portion of the second color filter layer 820 not overlapping other color filter layers may have a shape corresponding to the second color opening 502 of the bank 500, and a portion of the third color filter layer 830 not overlapping other color filter layers may have a shape corresponding to the third color opening 503 of the bank 500.

As described above, the emission layer included in the intermediate layer 303 located in the first pixel PX1, the second pixel PX2, and the third pixel PX3 may include the second color emission layer and the third color emission layer respectively emitting light having the second color wavelength and light having the third color wavelength. The second color filter layer 820 located in the second pixel PX2 may transmit only light having the second color wavelength (from among light having the second color wavelength and light having the third color wavelength emitted from the emission layer) in the second pixel PX2. The third color filter layer 830 located in the third pixel PX3 may transmit only light having the third color wavelength (from among light having the second color wavelength and light having the third color wavelength emitted from the emission layer) in the third pixel PX3. The first color filter layer 810 located in the first pixel PX1 may transmit light having the first color wavelength emitted from the quantum dot layer 610. Accordingly, light having the first color wavelength may be emitted from the first pixel PX1, light having the second color wavelength may be emitted from the second pixel PX2, and light having the third color wavelength may be emitted from the third pixel PX3. The first color wavelength may belong to a wavelength band of, for example, about 625 nm to about 780 nm, the second color wavelength may belong to a wavelength band of, for example, about 495 nm to about 570 nm, and the third color wavelength may belong to a wavelength band of, for example, about 450 nm to about 495 nm.

As such, the first color filter layer 810 and the second color filter layer 820 may enable the display apparatus to display a full-color image. For reference, the first color filter layer 810 may increase color purity if light passing through the quantum dot layer 610 is emitted to the outside, thereby improving the quality of a displayed image. Also, the first to third color filter layers 810, 820, and 830 may reduce a rate at which external light incident on the display apparatus is reflected by the first to third pixel electrodes 311, 312, and 313 and then is emitted back to the outside, thereby reducing external light reflection. A black matrix may be located between the first to third color filter layers 810, 820, and 830, if suitable.

The third color filter layer 830 includes a first filter opening 801 corresponding to the first light-emitting device as shown in FIG. 3. The first filter opening 801 of the third color filter layer 830 may define an area of the first pixel PX1. That is, in plan view, a shape and a size of the first pixel PX1 may be defined by the first filter opening 801 of the third color filter layer 830. The first color filter layer 810 fills at least the first filter opening 801 of the third color filter layer 830.

Also, as shown in FIG. 3, the third color filter layer 830 includes a second filter opening 802 corresponding to the second light-emitting device. The second filter opening 802 of the third color filter layer 830 may define an area of the second pixel PX2. That is, in plan view, a shape and a size of the second pixel PX2 may be defined by the second filter opening 802 of the third color filter layer 830. The second color filter layer 820 fills at least the second filter opening 802 of the third color filter layer 830.

Also, the first color filter layer 810 includes a third filter opening 803 corresponding to the third light-emitting device. The third filter opening 803 of the first color filter layer 810 may define an area of the third pixel PX3. That is, in plan view, a shape and a size of the third pixel PX3 may be defined by the third filter opening 803 of the first color filter layer 810. The third color filter layer 830 fills at least the third filter opening 803 of the first color filter layer 810. When the third color filter layer 830 is located closer to the upper substrate 900 than the first color filter layer 810 as shown in FIG. 3, the third color filter layer 830 may overlap the third filter opening 803 of the first color filter layer 810, rather than filling the third filter opening 803 of the first color filter layer 810.

The first color filter layer 810 may include an additional filter opening corresponding to the second light-emitting device as shown in FIG. 3, similar to the third color filter layer 830 including the second filter opening 802. The second color filter layer 820 may fill the second filter opening 802 of the third color filter layer 830 and the additional filter opening of the first color filter layer 810.

Because the third color filter layer 830 defines an area of the first pixel PX1 and an area of the second pixel PX2 through the first filter opening 801 and the second filter opening 802 as described above, the third color filter layer 830 may be referred to as a filter-defining layer in the first pixel PX1 and the second pixel PX2. Likewise, because the first color filter layer 810 defines an area of the third pixel PX3 through the third filter opening 803, the first color filter layer 810 may be referred to as a filter-defining layer in the third pixel PX3. These filter-defining layers may also be referred to as pixel area defining layers.

In this case, when viewed in the direction (the z axis direction) perpendicular to the lower substrate 100, the area of the third filter opening 803 of the first color filter layer 810 is greater than the area of the third pixel opening 153 of the pixel-defining film 150, the area of the first filter opening 801 of the third color filter layer 830 is greater than the area of the first pixel opening 151 of the pixel-defining film 150, and the area of the second filter opening 802 of the third color filter layer 830 is greater than the area of the second pixel opening 152 of the pixel-defining film 150. In this regard, in FIG. 3, when viewed in the direction (the z axis direction) perpendicular to the lower substrate 100, there is a distance d between an edge of the first filter opening 801 and an edge of the first pixel opening 151.

Through such a relationship between the areas of filter openings of color filter layers and the areas of pixel openings of a pixel-defining film, light generated from the first pixel opening 151 of the pixel-defining film 150 may be sufficiently incident into the first filter opening 801 of the third color filter layer 830 through the quantum dot layer 610, light generated from the second pixel opening 152 of the pixel-defining film 150 may be sufficiently incident into the second filter opening 802 of the third color filter layer 830, and light generated from the third pixel opening 153 of the pixel-defining film 150 may be sufficiently incident into the third filter opening 803 of the first color filter layer 810.

A portion where two or more color filter layers overlap each other may function as a black matrix. This is because, if the first color filter layer 810 transmits only light having a wavelength belonging to a wavelength band of about 625 nm to about 780 nm, and because the second color filter layer 820 transmits only light having a wavelength belonging to a wavelength band of about 450 nm to about 495 nm, light that may pass through both the first color filter layer 810 and the second color filter layer 820 does not exist, theoretically, in a portion where the first color filter layer 810 and the second color filter layer 820 overlap each other. Because a portion where all of the first color filter layer 810, the second color filter layer 820, and the third color filter layer 830 overlap each other exists between the first pixel PX1, the second pixel PX2, and the third pixel PX3, color filters may reliably function as a black matrix between the first pixel PX1, the second pixel PX2, and the third pixel PX3.

As described above, the quantum dot layer 610 located in the first pixel PX1 may include a scatterer. To display a uniform high-quality image, a scatterer may also be located in the second pixel PX2 and the third pixel PX3. In detail, a light-transmitting layer 520 including a scatterer may be located in the second color opening 502 and the third color opening 503 of the bank 500. If suitable, unlike in FIG. 3, the light-transmitting layer 520 may not be located in the second color opening 502 and the third color opening 503 of the bank 500. The light-transmitting layer 520 may include a light-transmitting resin and a scatterer.

The scatterer included in the light-transmitting layer 520 is not particularly limited as long as it is capable of partially scattering transmitted light by forming an optical interface between the scatterer and the light-transmitting resin. For example, the scatterer may be metal oxide particles or organic particles. Examples of a metal oxide for the scatterer may include titanium oxide (TiO₂), zirconium oxide (ZrO₂), aluminum oxide (Al₂O₃), indium oxide (In₂O₃), zinc oxide (ZnO or ZnO₂), and/or tin oxide (SnO₂), and examples of an organic material for the scatterer may include an acrylic resin and a urethane-based resin. The scatterer may scatter light in several directions regardless of an angle of incidence without substantially converting a wavelength of incident light. Accordingly, the scatterer may improve side visibility of the display apparatus.

The light-transmitting resin included in the light-transmitting layer 520 may be any resin as long as it has suitable distribution characteristics for the scatterer and is a light-transmitting material. For example, a polymer resin, such as an acrylic resin, an imide-based resin, an epoxy-based resin, BCB, or HMDSO may be used as the light-transmitting resin included in the light-transmitting layer 520. A material for forming the light-transmitting layer 520, which is a mixture of the light-transmitting resin and the scatterer, may be located in the second color opening 502 and the third color opening 503 of the bank 500 through inkjet printing.

A first inorganic layer 700 may be located between the bank 500 and the first to third color filter layers 810, 820, and 830. The first inorganic layer 700 may also be located between the quantum dot layer 610 and the first to third color filter layers 810, 820, and 830. In a manufacturing process, the first inorganic layer 700 may cover the first color filter layer 810, the second color filter layer 820, and the third color filter layer 830, and the bank 500 may be formed on a top surface of the first inorganic layer 700. The first inorganic layer 700 may include an inorganic material, such as silicon oxide, silicon nitride, or silicon oxynitride, and may be formed by using CVD. The first inorganic layer 700 may prevent, reduce, or minimize defects caused by penetration of impurities, such as gas generated in the first color filter layer 810, the second color filter layer 820, and/or the third color filter layer 830 into the quantum dot layer 610 or an emission layer of an organic light-emitting device under the quantum dot layer 610.

If suitable, a low refractive index layer may be located between the first inorganic layer 700 and the first to third color filter layers 810, 820, and 830. The low refractive index layer may include an inorganic material, such as silicon oxide, silicon nitride, or silicon oxynitride, and may be formed by using CVD.

A surface of the bank 500 facing the lower substrate 100 (in the-z direction), and a bottom surface of the quantum dot layer 610 facing the lower substrate 100 (in the-z direction), may be covered by a second inorganic layer 510. A bottom surface of the light-transmitting layer 520 facing the lower substrate 100 (in the-z direction) may also be covered by the second inorganic layer 510. The second inorganic layer 510 may protect the quantum dot layer 610. The second inorganic layer 510 may include an inorganic material, such as silicon nitride, silicon oxide, or silicon oxynitride.

The lower substrate 100 and the upper substrate 900 may be adhered to each other by using an adhesive member, such as a sealant outside a display area. In this case, a filler may be filled between a stack on the lower substrate 100 and a stack on the upper substrate 900 if suitable. For example, a filler may be filled between an encapsulation layer 400 and the second inorganic layer 510. The filler may include a resin, such as acryl resin or epoxy-based resin.

In the display apparatus, as described with reference to FIG. 2, when viewed in the direction (the z axis direction) perpendicular to the lower substrate 100, the set ST of the first color opening 501, the second color opening 502, and the third color opening 503 may be repeatedly arranged along the direction (the-id2 direction) opposite to the second inclination direction (the +id2 direction). In addition, the set ST of the first color opening 501, the second color opening 502, and the third color opening 503 may be repeatedly arranged along the first direction (the +x direction). Accordingly, the first color opening 501 may be located along the first direction (the +x direction) and the second direction (the +y direction). The second color opening 502 may be located along the first direction (the +x direction) and the second direction (the +y direction), and the third color opening 503 may also be located along the first direction (the +x direction) and the second direction (the +y direction). Furthermore, first and second virtual lines IL1 and IL2 passing through an edge of the first color opening 501 and extending in the first direction (the +x direction) might not overlap the third color opening 503. In other words, the third color opening 503 may be spaced apart from the first and second virtual lines IL1 and IL2 passing through an edge of the first color opening 501 and extending in the first direction (the +x direction) Due to this configuration, a high-quality image may be displayed.

For example, there may be considered a stripe pattern arrangement-type display apparatus in which each of the first color opening, the second color opening, and the third color opening has a stripe shape extending in the second direction (the +y direction), in which the first color opening, the second color opening, and the third color opening are sequentially arranged in the first direction (the +x direction), and in which the set of the first color opening, the second color opening, and the third color opening is repeatedly arranged in the first direction (the +x direction) and in the second direction (the +y direction). In the display apparatus, if data is applied so that white is displayed in the entire display area, because the third color openings are located along the second direction (the +y direction) at an end of the display area in the first direction (the +x direction), a blue line extending in the second direction (the +y direction) may appear at the end of the display area in the first direction (the +x direction). For the same reason, because the first color openings are located along the second direction (the +y direction) at an end of the display area in a direction (the −x direction) opposite to the first direction, a red line extending in the second direction (the +y direction) may appear at the end of the display area in the direction (the −x direction) opposite to the first direction.

However, in the display apparatus according to one or more embodiments of the present disclosure, the set ST of the first color opening 501, the second color opening 502, and the third color opening 503 is repeatedly arranged along the direction (the −id2 direction) opposite to the second inclination direction (the +id2 direction), and the set ST of the first color opening 501, the second color opening 502, and the third color opening 503 is repeatedly arranged along the first direction (the +x direction). Accordingly, as shown in FIG. 2, while the third color openings are located along the second direction (the +y direction) at an end of the display area in the first direction (the +x direction), the second color openings are located closer to the third color openings than those in the stripe pattern arrangement-type display apparatus. As a result, if data is applied so that white is displayed in the entire display area, a line extending along the second direction (the +y direction) at the end of the display area in the first direction (the +x direction) is a sky blue line that is closer to white, rather than a blue line. Likewise, as shown in FIG. 2, while the first color openings are located along the second direction (the +y direction) at an end of the display area in the direction (the −x direction) opposite to the first direction, the second color openings are located closer to the first color openings than those in the stripe pattern arrangement-type display apparatus. As a result, if data is applied so that white is displayed in the entire display area, a line extending along the second direction (the +y direction) at the end of the display area in the direction (the-x direction) opposite to the first direction is a yellow line that is closer to white, rather than a red line. Accordingly, the display apparatus may display a high-quality image.

There may be considered a triangular arrangement-type display apparatus in which the first color opening, the second color opening, and the third color opening are located at vertices of a triangle having a shape roughly similar to an equilateral triangle. For example, there may be considered a display apparatus in which the first color opening is located at a vertex in the direction (the −x direction) opposite to the first direction, the second color opening is located at a vertex in the second direction (the +y direction), the third color opening is located at a vertex in the first direction (the +x direction), a set of the first color opening, the second color opening, and the third color opening is repeatedly arranged in the first direction (the +x direction) and the second direction (the +y direction). In this display apparatus, if data is applied so that white is displayed in the entire display area, because the second color openings are located along the first direction (the +x direction) at an end of the display area in the second direction (the +y direction), a green line extending in the first direction (the +x direction) appears at the end of the display area in the second direction (the +y direction). For the same reason, because the first color openings and the third color openings are alternately arranged along the first direction (the +x direction) at an end of the display area in a direction (the −y direction) opposite to the second direction, a purple line extending in the first direction (the +x direction) appears at the end of the display area in the direction (the −y direction) opposite to the second direction.

However, in the display apparatus according to one or more embodiments of the present disclosure, the set ST of the first color opening 501, the second color opening 502, and the third color opening 503 is repeatedly arranged along the direction (the −id2 direction) opposite to the second inclination direction (the +id2 direction), and the set ST of the first color opening 501, the second color opening 502, and the third color opening 503 is repeatedly arranged along the first direction (the +x direction). Accordingly, as shown in FIG. 2, while the first color openings are located along the first direction (the +x direction) at an end of the display area in the second direction (the +y direction), the second color openings are located closer to the first color openings than those in the triangular arrangement-type display apparatus. As a result, if data is applied so that white is displayed in the entire display area, a line extending along the first direction (the +x direction) at the end of the display area in the second direction (the +y direction) is a yellow line that is closer to white, rather than a green line. Likewise, as shown in FIG. 2, while the third color openings are located along the first direction (the +x direction) at an end of the display area in the direction (the −y direction) opposite to the second direction, the second color openings are located closer to the third color openings than those in the triangular arrangement-type display apparatus. As a result, if data is applied so that white is displayed in the entire display area, a line extending along the first direction (the +x direction) at the end of the display area in the direction (the −y direction) opposite to the second direction is a sky blue line that is closer to white, rather than a purple line. Accordingly, the display apparatus may display a high-quality image.

To display a high-quality image, as described above, the first and second virtual lines IL1 and IL2 passing through an edge of the first color opening 501 and extending in the first direction (the +x direction) may not overlap the third color opening 503. In other words, the third color opening 503 is spaced apart from the first and second virtual lines IL1 and IL2 passing through an edge of the first color opening 501 and extending in the first direction (the +x direction). In detail, when viewed in the direction (the z axis direction) perpendicular to the lower substrate 100, the first virtual line IL1 passing through an edge of the first color opening 501 in the second direction (the +y direction) and extending in the first direction (the +x direction) may not overlap the third color opening 503. In other words, when viewed in the direction (the z axis direction) perpendicular to the lower substrate 100, the third color opening 503 is spaced apart from the first virtual line IL1 passing through an edge of the first color opening 501 in the second direction (the +y direction), and extending in the first direction (the +x direction). In this case, to display a high-resolution image, considering the third color opening 503 closest to the first color opening 501 in the second direction (the +y direction), the first virtual line IL1 may pass through an edge of the third color opening 503 in the direction (the −y direction) opposite to the second direction.

Unlike this, when viewed in the direction (the z axis direction) perpendicular to the lower substrate 100, considering the second color opening 502 closest to the first color opening 501 in the direction (the −y direction) opposite to the second direction, the second virtual line IL2 passing through an edge of the first color opening 501 in the direction (the −y direction) opposite to the second direction and extending in the first direction (the +x direction) may overlap the second color opening 502. That is, the second virtual line IL2 may pass through the second color opening 502.

When viewed in the direction (the z axis direction) perpendicular to the lower substrate 100, a third virtual line IL3 passing through an edge of the first color opening 501 in the direction (the −x direction) opposite to the first direction and extending in the second direction (the +y direction) may not overlap the third color opening 503. In other words, when viewed in the direction (the z axis direction) perpendicular to the lower substrate 100, the third color opening 503 is spaced apart from the third virtual line IL3 passing through an edge of the first color opening 501 in the direction (the −x direction) opposite to the first direction and extending in the second direction (the +y direction). In this case, to display a high-resolution image, considering the third color opening 503 closest to the first color opening 501 in the direction (the −x direction) opposite to the first direction, the third virtual line IL3 passing through an edge of the first color opening 501 in the direction (the −x direction) opposite to the first direction and extending in the second direction (the +y direction) may pass through an edge of the third color opening 503 in the first direction (the +x direction).

Unlike this, when viewed in the direction (the z axis direction) perpendicular to the lower substrate 100, considering the second color opening 502 closest to the first color opening 501 in the first direction (the +x direction), a fourth virtual line IL4 passing through an edge of the first color opening 501 in the first direction (the +x direction) and extending in the second direction (the +y direction) may overlap the second color opening 502. That is, the fourth virtual line IL4 may pass through the second color opening 502. Accordingly, as described above, if data is applied so that white is displayed in the entire display area, a line extending along the second direction (the +y direction) at an end of the display area in the direction (the −x direction) opposite to the first direction may be a yellow line that is closer to white, rather than a red line.

Like the first virtual line IL1, when viewed in the direction (the z axis direction) perpendicular to the lower substrate 100, a fifth virtual line IL5 passing through an edge of the first color opening 501 in the direction (the −id2 direction) opposite to the second inclination indirection and extending in the first inclination direction (the +id1 direction) may not overlap the third color opening 503. In other words, when viewed in the direction (the z axis direction) perpendicular to the lower substrate 100, the third color opening 503 is spaced apart from the fifth virtual line IL5 passing through an edge of the first color opening 501 in the direction (the −id2 direction) opposite to the second inclination indirection and extending in the first inclination direction (the +id1 direction). In one or more embodiments, to display a high-resolution image, considering the third color opening 503 closest to the first color opening 501 in the direction (the −id2 direction) opposite to the second inclination direction, the fifth virtual line IL5 may pass through an edge of the third color opening 503 in the second inclination direction (the +id2 direction).

Unlike this, when viewed in the direction (the z axis direction) perpendicular to the lower substrate 100, considering the second color opening 502 closest to the first color opening 501 in the second inclination direction (the +id2 direction), a sixth virtual line IL6 passing through an edge of the first color opening 501 in the second inclination direction (the +id2 direction) and extending in the first inclination direction (the +id1 direction) may overlap the second color opening 502. That is, the sixth virtual line IL6 may pass through the second color opening 502. Accordingly, a distance between the second color opening 502 and the third color opening 503 in the second inclination direction (the +id2 direction) may be reduced, and thus, a distance between the second color opening 502 and the third color opening 503 in the second direction (the +y direction) may be reduced. As a result, as described above, if data is applied so that white is displayed in the entire display area, a line extending along the first direction (the +x direction) at an end of the display area in the direction (the −y direction) opposite to the second direction may be a sky blue line that is closer to white, rather than a blue line.

Considering the second color opening 502 closest to the third color opening 503 in the direction (the −x direction) opposite to the first direction, a seventh virtual line

IL7 passing through an edge of the third color opening 503 in the direction (the −x direction) opposite to the first direction and extending in the second direction (the +y direction) may overlap the second color opening 502. That is, the seventh virtual line IL7 may pass through the second color opening 502. Accordingly, a distance between the second color opening 502 and the third color opening 503 in the first direction (the +x direction) may be reduced. As a result, as described above, if data is applied so that white is displayed in the entire display area, a line extending along the second direction (the +y direction) at an end of the display area in the first direction (the +x direction) may be a sky blue line that is closer to white, rather than a blue line.

Likewise, considering the second color opening 502 closest to the third color opening 503 in the second direction (the +y direction), an eighth virtual line IL8 passing through an edge of the third color opening 503 in the second direction (the +y direction) and extending in the first direction (the +x direction) may overlap the second color opening 502. That is, the eighth virtual line IL8 may pass through the second color opening 502. Accordingly, a distance between the second color opening 502 and the third color opening 503 in the second direction (the +y direction) may be reduced. As a result, as described above, if data is applied so that white is displayed in the entire display area, a line extending along the first direction (the +x direction) at an end of the display area in the direction (the −y direction) opposite to the second direction may be a sky blue line that is closer to white, rather than a purple line.

Unlike this, when viewed in the direction (the z axis direction) perpendicular to the lower substrate 100, considering the second color opening 502 closest to the third color opening 503 in the direction (the −id2 direction) opposite to the second inclination direction, a ninth virtual line IL9 passing through an edge of the third color opening 503 in the direction (the −id2 direction) opposite to the second inclination direction and extending in the first inclination direction (the +id1 direction) may overlap the second color opening 502. That is, the ninth virtual line IL9 may pass through the second color opening 502. Accordingly, a distance between the second color opening 502 and the third color opening 503 in the direction (the −id2 direction) opposite to the second inclination direction may be reduced, and thus, a distance between the second color opening 502 and the third color opening 503 in the first direction (the +x direction) may be reduced. As a result, as described above, if data is applied so that white is displayed in the entire display area, a line extending along the second direction (the +y direction) at an end of the display area in the first direction (the +x direction) may be a sky blue line that is closer to white, rather than a blue line.

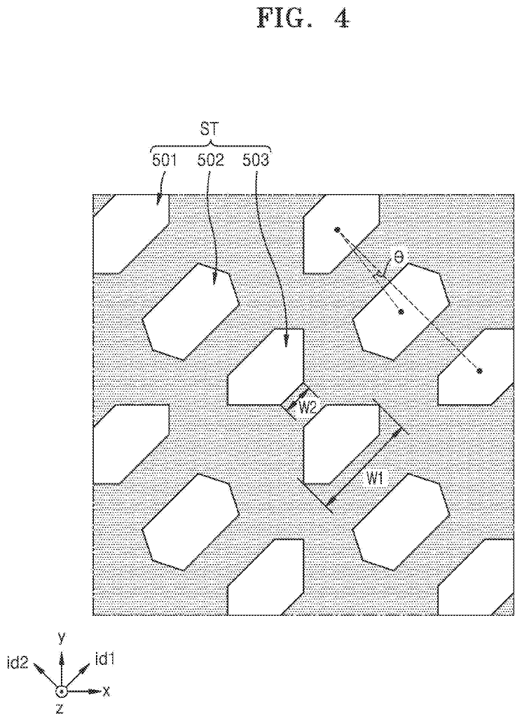

FIG. 4 is an enlarged plan view illustrating a portion of the display apparatus of FIG. 2.

Considering the first color opening 501, and the third color opening 503 closest to the first color opening 501 in the second inclination direction (the +id2 direction), a width of the first color opening 501 in the first inclination direction (the +id1 direction) may be W1, and a width, in the first inclination direction (the +id1 direction), of an edge of the third color opening 503 in the direction (the −id2 direction) opposite to the second inclination direction may be W2. W2/W1 (width ratio) may be about 0.55 or less.

When W2/W1 increases, it means that a width, in the first inclination direction (the +id1 direction), of an edge of the third color opening 503 in the direction (the −id2 direction) opposite to the second inclination direction relatively increases in view of a width of the first color opening 501 in the first inclination direction (the +id1 direction). In this case, part of light emitted from the first light-emitting device corresponding to the first color opening 501 may enter the third color opening 503, which causes color mixing and reduces or prevents the likelihood of the display apparatus displaying a high-quality image. When W2/W1 is greater than about 0.55, a rate at which color mixing occurs rapidly increases. Accordingly, W2/W1 may suitably be about 0.55 or less.

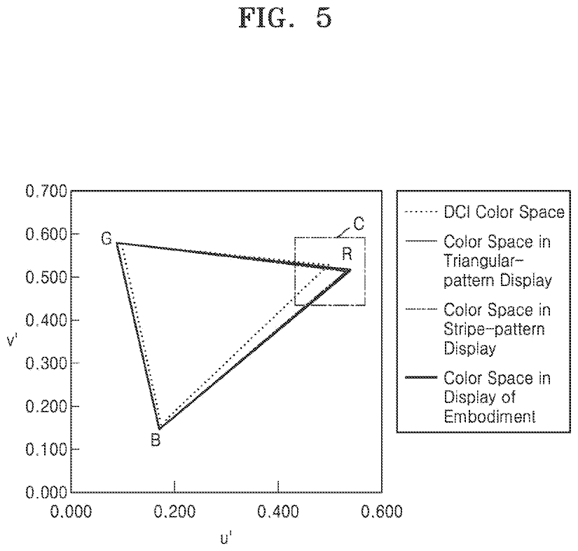

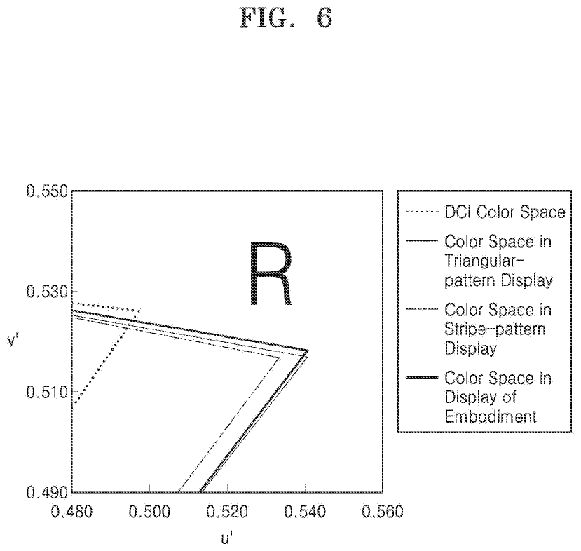

FIG. 5 is a graph schematically illustrating a DCI color space and a color space of the display apparatus of FIG. 1. FIG. 6 is an enlarged graph illustrating a portion C of FIG. 5. In FIGS. 5 and 6, a DCI color space, which is a color space for digital movie projection in the U.S. film industry commonly used in the display field, is shown by a dotted line, a color space appearing in the triangular arrangement-type display apparatus is shown by a thin solid line, a color space appearing in the stripe pattern arrangement-type display apparatus is shown in a two-dot dashed line, and a color space appearing in the display apparatus according to one or more embodiments of the present disclosure is shown by a thick solid line.

As shown in FIG. 5, for green (G) and blue (B), all of the triangular arrangement-type display apparatus, the stripe pattern arrangement-type display apparatus, and the display apparatus according to one or more embodiments of the present disclosure may express both green and blue in the DCI color space. This is because green and blue in the DCI color space are located in the color space of the triangular arrangement-type display apparatus, the color space of the stripe pattern arrangement-type display apparatus, and the color space of the display apparatus according to one or more embodiments of the present disclosure.

However, this is not the case for red (R). As shown in FIG. 6, which is an enlarged graph illustrating a portion C including a red (R) portion in the graph of FIG. 5, red in the DCI space is not located in the color space of the triangular arrangement-type display apparatus, the color space of the stripe pattern arrangement-type display apparatus, and the color space of the display apparatus according to one or more embodiments of the present disclosure. In this case, as a color space of a display apparatus according to one or more embodiments of the present disclosure is closer to the DCI space, the display apparatus according to one or more embodiments of the present disclosure may have a higher color reproduction rate.

That is, in color coordinates in which a horizontal axis is u′ and a vertical axis is v′, because a u′ value corresponding to red in each of the color space of the triangular arrangement-type display apparatus, the color space of the stripe pattern arrangement-type display apparatus, and the color space of the display apparatus according to one or more embodiments of the present disclosure is greater than a u′ value corresponding to red in the DCI color space, as a v′ value corresponding to red in each of the color space of the triangular arrangement-type display apparatus, the color space of the stripe pattern arrangement-type display apparatus, and the color space of the display apparatus according to one or more embodiments of the present disclosure is closer to a v′ value corresponding to red in the DCI space, the display apparatus may have a higher color reproduction rate.

As shown in FIG. 6, a v′ value corresponding to red in the color space of the display apparatus according to one or more embodiments of the present disclosure is greater than a v′ value corresponding to red in the color space of the triangular arrangement-type display apparatus or the color space of the stripe pattern arrangement-type display apparatus, and is closer to a v′ value corresponding to red in the DCI color space. Accordingly, it is found that a color reproduction rate of the display apparatus according to one or more embodiments of the present disclosure is suitable.

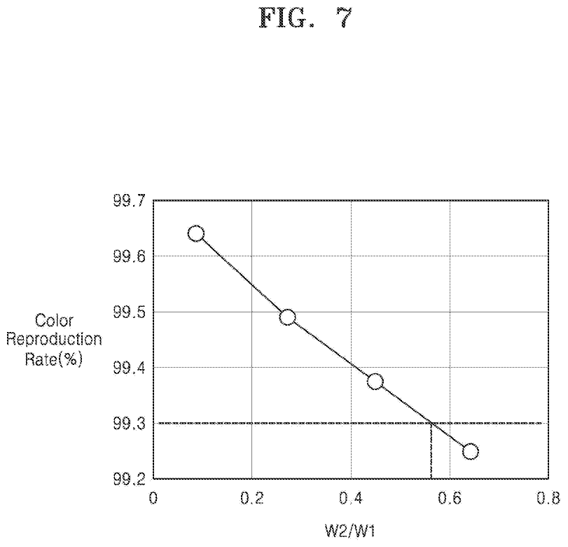

FIG. 7 is a graph illustrating a color reproduction rate according to a width ratio of W2/W1 in openings of a bank of the display apparatus of FIG. 1. A horizontal axis is W2/W1, and a vertical axis is a ratio of the area of a portion where a color space of a display apparatus according to one or more embodiments of the present disclosure and a DCI color space overlap each other to the area of the DCI color space. That is, the vertical axis represents a color reproduction rate of the display apparatus according to one or more embodiments of the present disclosure, and as a value in the vertical axis increases, the display apparatus may be better. For a display apparatus capable of displaying a high-quality image, a color reproduction rate may be about 99.3% or more. Accordingly, it is found that W2/W1 is about 0.55 if a color reproduction rate is about 99.3%. Accordingly, W2/W1 may suitably be about 0.55 or less.

As W2/W1 decreases, defects may occur in a process of forming the third color opening 503 in the bank 500. As described above, a width, in the first inclination direction (the +id1 direction) of an edge of the third color opening 503 in the direction (the −id2 direction) opposite to the second inclination direction, that is, a width of an edge of the third color opening 503 facing the first color opening 501 in the first inclination direction (the +id1 direction), is W2. As W2/W1 decreases, it means that W2 that is a width of an edge of the third color opening 503 facing the first color opening 501 in the first inclination direction (the +id1 direction) decreases, and thus, a portion of the third color opening 503 facing the first color opening 501 becomes sharper. When W2/W1 is less than about 0.1, a portion of the third color opening 503 facing the first color opening 501 is excessively sharp. This may cause a rapid increase in a defect rate in a process of forming the third color opening 503 in the bank 500 when the display apparatus is manufactured. Accordingly, it may be suitable that W2/W1 is about 0.1 or more.

As shown in FIG. 4, a first straight line connecting the center of the first color opening 501 to the center of the second color opening 502, and a second straight line connecting the center of the first color opening 501 to the center of the third color opening 503, may form an acute angle θ therebetween. The acute angle θ may be about 1° or more and about 20° or less.

When the acute angle θ is less than about 1°, it means that the first color opening 501, the second color opening 502, and the third color opening 503 are almost aligned in the second inclination direction (the +id2 direction).

As shown in FIG. 3, a constant distance may be maintained between a structure formed on the lower substrate 100 and a structure formed on the upper substrate 900. To this end, a spacer may be located between the structure formed on the lower substrate 100 and the structure formed on the upper substrate 900. When viewed in the direction (the z axis direction) perpendicular to the lower substrate 100, the spacer does not overlap the first color opening 501, the second color opening 502, and the third color opening 503 of the bank 500. In other words, when viewed in the direction (the z axis direction) perpendicular to the lower substrate 100, the spacer is spaced apart from the first color opening 501, the second color opening 502, and the third color opening 503 of the bank 500.

When the acute angle θ is less than about 1°, it means that the first color opening 501, the second color opening 502, and the third color opening 503 are almost aligned in the second inclination direction (the +id2 direction), and in this case, a space for the spacer may not be secured in a situation where a distance between the first color opening 501, the second color opening 502, and the third color opening 503 is narrow to display a high-resolution image. Accordingly, it may be suitable that the acute angle θ is about 1° or more. When the acute angle θ is greater than about 20°, a space occupied by the set ST of the first color opening 501, the second color opening 502, and the third color opening 503 is excessively large, thereby making it difficult to realize a display apparatus for displaying a high-resolution image. Accordingly, it may be suitable that the acute angle θ is about 1° or more and about 20° or less.

Although each of the first light-emitting device, the second light-emitting device, and the third light-emitting device emits light having the second color wavelength and light having the third color wavelength, the disclosure is not limited thereto. For example, each of the first light-emitting device, the second light-emitting device, and the third light-emitting device may emit light having the third color wavelength. In this case, the light-transmitting layer 520 is not located in the second color opening 502 of the bank 500, but instead an additional quantum dot layer may be used. The additional quantum dot layer may convert light having the third color wavelength emitted from the second light-emitting device into light having the second color wavelength. The quantum dot layer 610 located in the first color opening 501 of the bank 500 may convert light having the third color wavelength emitted from the first light-emitting device into light having the first color wavelength. For reference, light having the third color wavelength emitted from the third light-emitting device passes through the light-transmitting layer 520 located in the third color opening 503 of the bank 500. As such, the description of a case where each of the first light-emitting device, the second light-emitting device, and the third light-emitting device emits light having the third color wavelength may apply to the following embodiments and modifications thereof.

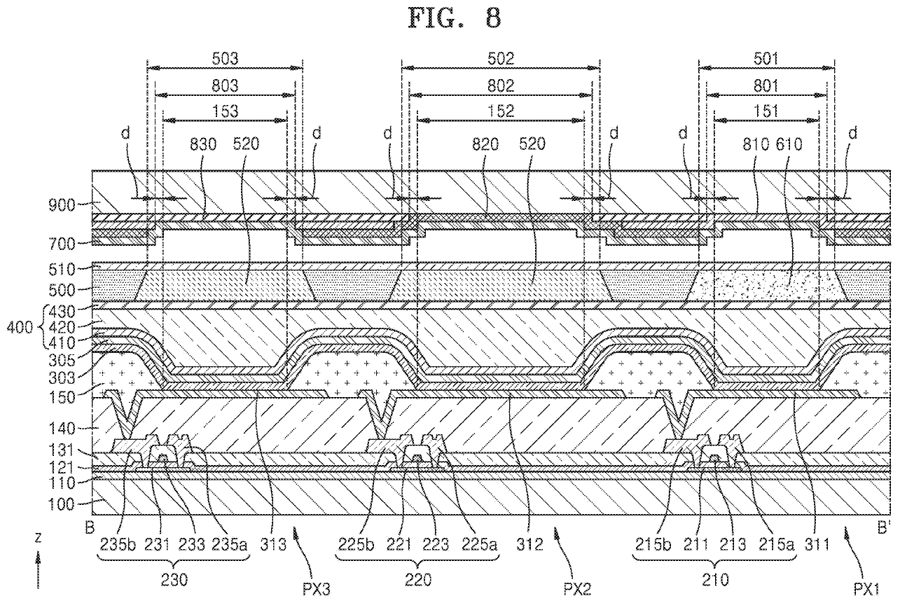

FIG. 8 is a cross-sectional view schematically illustrating a display apparatus, according to one or more embodiments. A difference between the display apparatus and the display apparatus of FIG. 3 is a position of the bank 500. Overlapping description that is the same as that made with reference to FIG. 3 will be omitted for convenience, and only differences will be described.

In the display apparatus, the bank 500 is not located over a bottom surface of the upper substrate 900 facing the lower substrate 100, but is located over the encapsulation layer 400 formed above the lower substrate 100. When viewed in the direction (the z axis direction) perpendicular to the lower substrate 100, the bank 500 includes the first color opening 501, the second color opening 502, and the third color opening 503 respectively overlapping the first light-emitting device, the second light-emitting device, and the third light-emitting device.

The quantum dot layer 610 is located in the first color opening 501 to overlap the first light-emitting device, when viewed in the direction (the z axis direction) perpendicular to the lower substrate 100. The light-transmitting layers 520 are located in the second color opening 502 and the third color opening 503 to overlap the second light-emitting device and the third light-emitting device, when viewed in the direction (the z axis direction) perpendicular to the lower substrate 100. A top surface of the bank 500 facing the upper substrate 900 (in the +z direction) and a top surface of the quantum dot layer 610 facing the upper substrate 900 (in the +z direction) may be covered by the second inorganic layer 510. A top surface of the light-transmitting layer 520 facing the upper substrate 900 (in the +z direction) may also be covered by the second inorganic layer 510.

The second inorganic layer 510 may protect the quantum dot layer 610. The second inorganic layer 510 may include an inorganic material, such as silicon nitride, silicon oxide, or silicon oxynitride.

The first color filter layer 810, the second color filter layer 820, and the third color filter layer 830 may be located over a surface of the upper substrate 900 facing the lower substrate 100 (in the-z direction) as described with reference to FIG. 3, and the first inorganic layer 700 may cover the first color filter layer 810, the second color filter layer 820, and the third color filter layer 830. The first inorganic layer 700 may include an inorganic material, such as silicon oxide, silicon nitride, or silicon oxynitride, and may be formed by using CVD. The first inorganic layer 700 may prevent, reduce, or minimize defects caused by penetration of impurities, such as gas generated in the first color filter layer 810, the second color filter layer 820, and/or the third color filter layer 830 into the quantum dot layer 610 or an emission layer of an organic light-emitting device under the quantum dot layer 610.

As shown in FIG. 8, a constant distance may be maintained between a structure formed on the lower substrate 100 and a structure formed on the upper substrate 900. To this end, a spacer may be located between the structure formed on the lower substrate 100 and the structure formed on the upper substrate 900. The spacer may be located between the second inorganic layer 510 on the lower substrate 100 and the first inorganic layer 700 on the upper substrate 900. The spacer may be formed of any of various materials. For example, the spacer may include a photoresist material, or an inorganic material, such as silicon oxide, silicon nitride, or silicon oxynitride.

Even in the display apparatus according to one or more embodiments of the present disclosure, a positional relationship between the first color opening 501, the second color opening 502, and the third color opening 503 described with reference to FIG. 3 may be applied.

Although a positional relationship between the first color opening 501, the second color opening 502, and the third color opening 503 has been described, the disclosure is not limited thereto. For example, a positional relationship between the first color opening 501, the second color opening 502, and the third color opening 503 of the bank 500 may apply to a positional relationship between a portion of the first color filter layer 810 not overlapping other color filter layers, a portion of the second color filter layer 820 not overlapping other color filter layers, and a portion of the third color filter layer 830 not overlapping other color filter layers.

As described above, according to one or more embodiments, a display apparatus capable of displaying a high-quality image may be realized. However, the scope of the disclosure is not limited by this effect.

It should be understood that embodiments described herein should be considered in a descriptive sense only and not for purposes of limitation. Descriptions of aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims, with functional equivalents thereof to be included therein.

1 What is claimed is:

1. A display apparatus comprising:
a lower substrate;
first light-emitting devices, second light-emitting devices, and third light-emitting devices above the lower substrate; and
a bank above the first light-emitting devices, the second light-emitting devices, and the third light-emitting devices, and defining first color openings, second color openings, and third color openings respectively corresponding to the first light-emitting devices, the second light-emitting devices, and the third light-emitting devices,
wherein, in plan view, sets of the first color opening, the second color opening, and the third color opening are repeatedly arranged along a first direction and along a direction opposite to a second inclination direction, the second inclination direction being perpendicular to a first inclination direction that is between the first direction and a second direction, the second direction being perpendicular to the first direction, and
wherein, in plan view, the third color opening is spaced apart from a virtual line passing through an edge of the first color opening and extending in the first direction.

2. The display apparatus of claim 1, wherein, in plan view, the third color opening is spaced apart from a third virtual line passing through an edge of the first color opening corresponding to a direction opposite to the first direction, the third virtual line extending in the second direction.

3. The display apparatus of claim 1, wherein, in plan view, a third virtual line passes through an edge of the first color opening corresponding to a direction opposite to the first direction, extends in the second direction, and passes through an edge of the third color opening corresponding to the first direction.

4. The display apparatus of claim 1, wherein, in plan view, the third color opening is spaced apart from first virtual line passing through an edge of the first color opening corresponding to the second direction and extending in the first direction.

5. The display apparatus of claim 1, wherein, in plan view, a first virtual line passes through an edge of the first color opening corresponding to the second direction, extends in the first direction, and passes through an edge of the third color opening corresponding to a direction opposite to the second direction.

6. The display apparatus of claim 1, wherein, in plan view, the first color openings are arranged along the first direction and the second direction.

7. The display apparatus of claim 6, wherein, in plan view, the second color openings are arranged along the first direction and the second direction, and the third color openings are arranged along the first direction and the second direction.

8. The display apparatus of claim 1, wherein, in plan view, a fourth virtual line passes through an edge of the first color opening corresponding to the first direction, extends in the second direction, and overlaps the second color opening.

9. The display apparatus of claim 8, wherein, in plan view, a second virtual line passes through an edge of the first color opening corresponding to a direction opposite to the second direction, extends in the first direction, and overlaps the second color opening.

10. The display apparatus of claim 1, wherein, in plan view, the third color opening is spaced apart from a fifth virtual line passing through an edge of the first color opening corresponding to the direction opposite to the second inclination direction, and extending in the first inclination direction.

11. The display apparatus of claim 1, wherein, in plan view, a fifth virtual line passes through an edge of the first color opening corresponding to the direction opposite to the second inclination direction, extends in the first inclination direction, and passes through an edge of the third color opening in the second inclination direction.

12. The display apparatus of claim 1, wherein, in plan view, a sixth virtual line passes through an edge of the first color opening in the second inclination direction, extends in the first inclination direction, and overlaps the second color opening.

13. The display apparatus of claim 1, wherein, in plan view, a seventh virtual line passes through an edge of the third color opening corresponding to a direction opposite to the first direction, extends in the second direction, and overlaps the second color opening.

14. The display apparatus of claim 1, wherein, in plan view, an eighth virtual line passes through an edge of the third color opening in the second direction, extends in the first direction, and overlaps the second color opening.

15. The display apparatus of claim 1, wherein, in plan view, a ninth virtual line passes through an edge of the third color opening corresponding to the direction opposite to the second inclination direction, extends in the first inclination direction, and overlaps the second color opening.

16. The display apparatus of claim 1, wherein a width of the first color opening in the first inclination direction is W1,
wherein a width of an edge of the third color opening corresponding to the direction opposite to the second inclination direction, in the first inclination direction is W2, and
wherein W2/W1 is about 0.55 or less.

17. The display apparatus of claim 16, wherein W2/W1 is about 0.1 or more.

18. The display apparatus of claim 1, wherein a first straight line connecting a center of the first color opening to a center of the second color opening, and a second straight line connecting the center of the first color opening to a center of the third color opening, form an acute angle therebetween.

19. The display apparatus of claim 18, wherein the acute angle is about 20° or less.

20. The display apparatus of claim 19, wherein the acute angle is about 1° or more.

21. The display apparatus of claim 1, further comprising a quantum dot layer in the first color opening, and configured to convert a wavelength of light emitted from one of the first light-emitting devices into a first color wavelength.

22. The display apparatus of claim 21, wherein the first color wavelength is in a red wavelength band.

23. The display apparatus of claim 21, further comprising a color filter layer above the bank, and comprising:
first color filter layers corresponding to the first color openings and configured to transmit light in a first color wavelength band;
second color filter layers corresponding to the second color openings and configured to transmit light in a second color wavelength band; and
third color filter layers corresponding to the third color openings and configured to transmit light in a third color wavelength band.
